(19) United States
(12) Patent Application Publication
(10) Pub. No.: US 2025/0262684 A1
(43) Pub. Date: Aug. 21, 2025

(54) DISSIMILAR METAL JOINED BODY, AND METHOD FOR JOINING DISSIMILAR METAL JOINED BODY

(71) Applicant: KAGA, INC., Tokyo (JP)

(72) Inventors: Kazumasa FUJII, Ishikawa (JP); Shu MATSUURA, Ishikawa (JP); Akio KOBAYASHI, Ishikawa (JP)

(73) Assignee: KAGA, INC., Tokyo (JP)

(21) Appl. No.: 18/858,452

(22) PCT Filed: Apr. 3, 2023
(86) PCT No.: PCT/JP2023/013761

§ 371 Date: Oct. 21, 2024

(30) Foreign Application Priority Data
May 13, 2022 (JP) 2022-079290

(51) Int. Cl. B23K 20/00; B23K 20/10; B23K 103/10; B23K 103/12; B23K 103/18; F16B 5/08

(52) U.S. Cl. CPC B23K 20/002; B23K 20/10; F16B 5/08; B23K 2103/10; B23K 2103/12; B23K 2103/18

(57) ABSTRACT

The dissimilar metal joined body in which three or more members including at least a first member, a second member, and a third member are joined and at least the first member and the second member are metal members each including one type of metal, different for each of the first member and the second member. The second member is in a column member insertion hole formed on a first surface of the third member, an annular rib of the first member is in a rib insertion hole formed on a second surface of the third member, and the second member, the annular rib and the rib insertion hole are shaped in a barrel shape.

### TECHNICAL FIELD

The present invention relates to a dissimilar metal joined body obtained by joining a plurality of members including different metal materials and a method for joining the dissimilar metal joined body.

### BACKGROUND ART

Conventionally, as a method for joining a plurality of members including different metal materials, various methods have been known such as mechanical joining such as bolt nuts, rivets, caulking, or shrink fitting; chemical joining such as adhesive; or material joining such as melting joining.

Furthermore, as a dissimilar metal joined body in which a plurality of members including different metal materials are mechanically connected, a dissimilar metal joined body has been known in which, in a state where a through hole is formed in a first metal body and a second metal body is fitted into the through hole, these metal bodies are compressed and joined in a flat plate shape. (for example, PTL 1)

### CITATION LIST

### Patent Literature

[PTL 1] Japanese Patent Application Publication No. 2020-82182

### SUMMARY OF INVENTION

### Technical Problem

Various joining methods that have been conventionally known have advantages and disadvantages, e.g., joining strength is weak although joining is easily implemented (adhesive or the like), the joining is not easily implemented and productivity is poor although the joining strength is strong (caulking, shrink fitting, or the like), an application is limited due to restriction on a shape and a structure although the joining strength is strong and the joining process is easily implemented (bolt nut or the like), or the like. Therefore, there has been a problem in that at least one disadvantage needs to be permitted.

Furthermore, a joining method disclosed in PTL 1 has a problem in that different metal materials are exposed in the same plane although the joining strength is strong and the joining is easily implemented, and the application thereof is restricted.

Therefore, an object of the present invention is to solve the above problems and to provide a dissimilar metal joined body with excellent joining strength, productivity, and versatility and a method for joining the dissimilar metal joined body.

### Means for Solving the Problem

To solve such a problem, the present invention has the following configuration.

A dissimilar metal joined body in which three or more members including at least a first member, a second member, and a third member are joined, in which at least the first member and the second member are metal members each including one type of metal, different for each of the first member and the second member and selected from among two or more types of metals, the first member has a flat plate shaped base part and an annular rib on a first surface of the flat plate shaped base part, the second member is a column member and is provided in an inner circumference surface of the annular rib of the first member, the third member has a substantially flat board shape in which the second member is in a column member insertion hole formed on a first surface of the third member and the annular rib of the first member is in a rib insertion hole formed on a second surface of the third member, and on a cross section including a central axis of the annular rib, the second member is shaped in a barrel shape, the annular rib is shaped in a shape expanded to an outer circumference side along an outer shape of the barrel shape of the second member, and the rib insertion hole of the third member is shaped in a shape expanded to the outer circumference side along the expanded shape of the annular rib.

Furthermore, the present invention has the following configuration.

A method for joining a dissimilar metal joined body in which three or more members including at least a first member, a second member, and a third member are joined, at least the first member and the second member being metal members each including one type of metal, different for each of the first member and the second member and selected from among two or more types of metals, the first member having a flat plate shaped base part and an annular rib on a first surface of the flat plate shaped base part, the second member being a column member that is inserted into an inner circumference surface of the annular rib of the first member and is higher than a height of the annular rib, and the third member having a substantially flat board shape lower than a height of the second member and having a column member insertion hole on a first surface in which the second member can be inserted, and having an annular rib insertion hole, on a second surface, which communicates with the column member insertion hole and into which the annular rib of the first member and an inner circumference part of the annular rib can be inserted, the method including: assembling through inserting the annular rib of the first member into the rib insertion hole of the third member and through inserting the second member into the column member insertion hole of the third member and the annular rib of the first member; and compressing and joining through compressing the first member, the second member, and the third member assembled by the assembling by pinching the second member protruding from the second surface of the third member and a surface of the first member where the annular rib is not formed and ending the compression at a time when a protruding part of the second member is flush with the second surface of the third member, so as to join the three or more members.

Furthermore, the present invention has the following configuration.

A dissimilar metal joined body in which two or more members including at least a first member and a second member are joined, in which at least the first member and the second member are metal members each including one type of metal, different for each of the first member and the second member and selected from among two or more types of metals, the first member has a flat plate shaped base part and an annular rib on a first surface of the flat plate shaped base part, the second member has a substantially flat board shape in which the annular rib of the first member is provided in an annular groove part formed in a first surface of the second member, and on a cross section including a central axis of the annular rib, a part of the second member in the annular rib of the first member is shaped in a barrel shape, the annular rib is shaped in a shape expanded to an outer circumference side along an outer shape of the barrel shape of the part of the second member in the annular rib of the first member, and the annular groove part of the second member is shaped in a shape expanded to the outer circumference side along the expanded shape of the annular rib.

Furthermore, the present invention has the following configuration.

A method for joining a dissimilar metal joined body in which two or more members including at least a first member and a second member are joined, at least the first member and the second member being metal members each including one type of metal, different for each of the first member and the second member and selected from among two or more types of metals, the first member having a flat plate shaped base part and an annular rib on a first surface of the flat plate shaped base part, the second member having a substantially flat board shape, having a protruding part for protruding an area, which substantially faces an inner part of an inner circumference surface of the annular rib when the first member and the second member are assembled, from other area, on a first surface, and having an annular groove part into which the annular rib can be inserted, on a second surface, the method including: assembling through inserting the annular rib of the first member into the annular groove part of the second member, and compressing and joining through compressing the first member and the second member assembled by the assembling by pinching the protruding part of the second member and a surface of the first member where the annular rib is not formed and ending the compression at a time when the protruding part of the second member is flush with the other area of the first surface of the second member, so as to join the two or more members.

Furthermore, the present invention has the following configuration.

A method for joining a dissimilar metal joined body in which two or more members including at least a first member and a second member are joined, at least the first member and the second member being metal members each including one type of metal, different for each of the first member and the second member and selected from among two or more types of metals, the first member having a flat plate shaped base part and an annular rib on a first surface of the flat plate shaped base part, the second member having a substantially flat board shape, having a first protruding part for protruding an area, which substantially faces an inner part of an inner circumference surface of the annular rib when the first member and the second member are assembled, from other area, on a first surface, having an annular groove part into which the annular rib can be inserted, and having a second protruding part for protruding an area, which is inserted into the inner part of the inner circumference surface of the annular rib when the first member and the second member are assembled, from other area, on a second surface, the method including: assembling through inserting the annular rib of the first member into the annular groove part of the second member and compressing and joining through compressing the first member and the second member assembled by the assembling by pinching the first protruding part of the second member and a surface of the first member where the annular rib is not formed and ending the compression at a time when the first protruding part of the second member is flush with the other area of the first surface of the second member and the second protruding part of the second member is flush with the other area of the second surface of the second member, so as to join the two or more members.

Furthermore, the present invention has the following configuration.

A method for joining a dissimilar metal joined body in which two or more members including at least a first member and a second member are joined, at least the first member and the second member being metal members each including one type of metal, different for each of the first member and the second member and selected from among two or more types of metals, the first member having a flat plate shaped base part and an annular rib on a first surface of the flat plate shaped base part, the second member having a substantially flat board shape, having a first surface that is a flat surface, and having an annular groove part into which the annular rib can be inserted and a protruding part for protruding an area, which is inserted into an inner part of an inner circumference surface of the annular rib when the first member and the second member are assembled, from other area, on a second surface, the method including: assembling through inserting the annular rib of the first member into the annular groove part of the second member; and compressing and joining through compressing the first member and the second member assembled by the assembling by pinching the first surface of the second member and a surface of the first member where the annular rib is not formed and ending the compression at a time when the protruding part of the second member is flush with the other area of the second surface of the second member, so as to join the two or more members.

### Advantageous Effects of Invention

The present invention can provide a dissimilar metal joined body and a method for joining the dissimilar metal joined body with excellent joining strength, productivity, and versatility by adopting a configuration in which, on a cross section including a central axis of an annular rib of a first member, a second member is shaped in a barrel shape, the annular rib is shaped in a shape expanded to an outer circumference side in accordance with an outer shape of the barrel shape of the second member, and a rib insertion hole of a third member is shaped in a shape expanded to an outer circumference side in accordance with the expanded shape of the annular rib.

### BRIEF DESCRIPTION OF DRAWINGS

FIG. 1 is a perspective view of a dissimilar metal joined body 1 according to an Embodiment 1 of the present invention; and FIG. 1 at (a) is a view illustrating a state before joining, and FIG. 1 at (b) is a view illustrating a state after joining.

FIG. 2 is a view illustrating assembling to assemble a first member 11, a second member 12, and a third member 13 according to the Embodiment 1 of the present invention.

FIG. 3 is a view illustrating compressing and joining to compress and join the first member 11, the second member 12, and the third member 13 that are assembled according to the Embodiment 1 of the present invention; and FIG. 3 at (a) is a view illustrating a state before joining, and FIG. 3 at (b) is a view illustrating a state after joining.

FIG. 4 is a view in which compressing and joining by a press machine is shaping-processed and simulated according to the Embodiment 1 of the present invention; and FIG. 4 at (a) is a view illustrating a state before joining, and FIG. 4 at (b) is a view illustrating a state after joining.

FIG. 5 is an X-ray CT image of the dissimilar metal joined body 1 according to the Embodiment 1 of the present invention.

FIG. 6 is a cross-sectional view of a modification 1 of the Embodiment 1 of the present invention.

FIG. 7 is a view illustrating assembling to assemble a first member 11 and a fourth member 14 according to an Embodiment 2 of the present invention.

FIG. 8 is a view illustrating compressing and joining to assemble and join the first member 11 and the fourth member 14 that are assembled according to the Embodiment 2 of the present invention; and FIG. 8 at (a) is a view illustrating a state before joining, and FIG. 8 at (b) is a view illustrating a state after joining.

FIG. 9 is a view in which compressing and joining by a press machine is shaping-processed and simulated according to the Embodiment 2 of the present invention; and FIG. 9 at (a) is a view illustrating a state before joining; and FIG. 9 at (b) is a view illustrating a state after joining.

FIG. 10 is a view illustrating compressing and joining to compress and join a first member 11 and a fifth member 15 that are assembled according to an Embodiment 3 of the present invention.

FIG. 11 is a view in which compressing and joining by a press machine is shaping-processed and simulated according to the Embodiment 3 of the present invention; and FIG. 11 at (a) is a view illustrating a state before joining, and FIG. 11 at (b) is a view illustrating a state after joining.

FIG. 12 is a view illustrating a dissimilar metal joined body of the present invention to be used as an electrode of a lithium ion battery.

### DESCRIPTION OF EMBODIMENTS

Hereinafter, a dissimilar metal joined body 1 according to embodiments of the present invention will be described with reference to the drawings.

In the following description, the same reference numerals in different figures indicate a portion having the same function, and redundant description in each figure is appropriately omitted.

### Embodiment 1

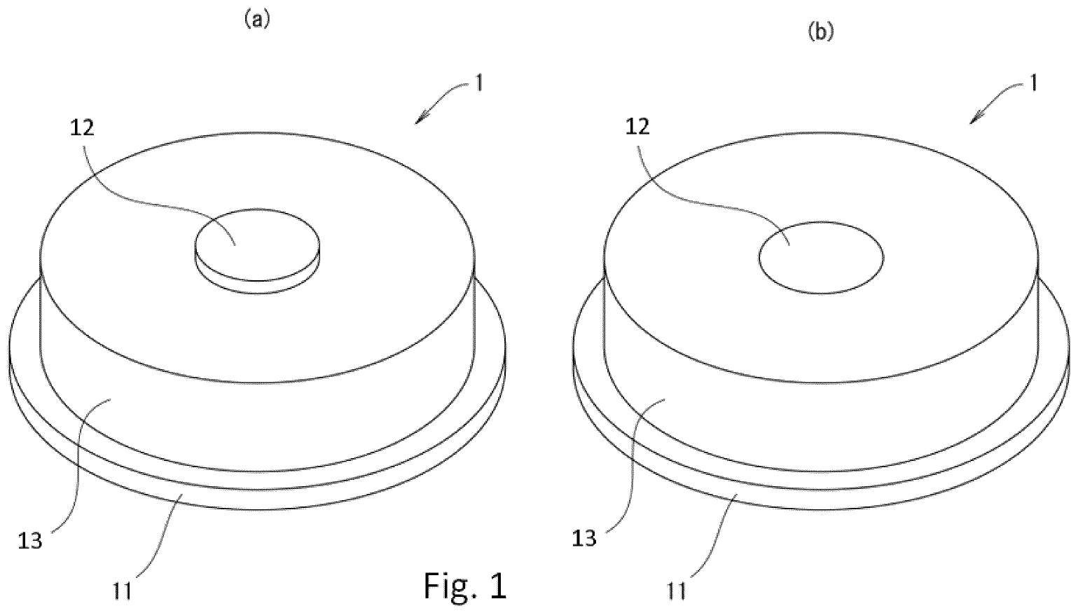

FIG. 1 is a perspective view of the dissimilar metal joined body 1 according to an Embodiment 1 of the present invention; and FIG. 1 at (a) is a view illustrating a state before joining, and FIG. 1 at (b) is a view illustrating a state after joining.

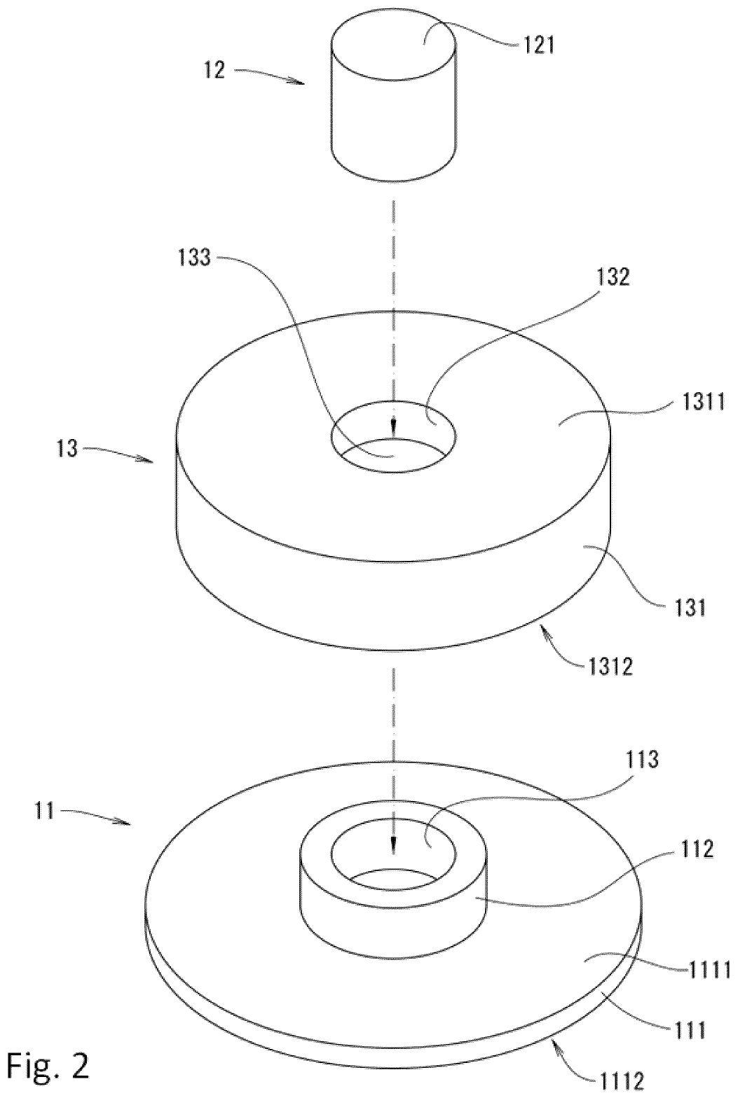

FIG. 2 is a view illustrating a state where a first member 11, a second member 12, and a third member 13 are assembled.

### [Configuration of Each Member]

The dissimilar metal joined body 1 according to the Embodiment 1 is formed of three metal members including the first member 11, the second member 12, and the third member 13.

The first member 11 is a member obtained by shaping copper, and includes a disk shaped base part 111 and an annular rib 112 provided so as to protrude from a central part on a first surface 1111 of the base part 111.

The second member 12 is a member obtained by shaping aluminum and is a column member that can be inserted into an inner circumference part 113 of the annular rib 112 of the first member 11 with no space and has a height in an axial direction higher than a height of the annular rib 112.

The third member 13 is a member obtained by shaping aluminum and includes a body part 131 formed in a disk-like shape as a whole, a column member insertion hole 132 formed in a first surface 1311 of the body part 131 and into which the second member 12 can be inserted with no space, and a rib insertion hole 133 that is formed in a second surface 1312 of the body part 131 and into which the annular rib 112 of the first member 11 and the inner circumference part 113 of the annular rib 112 can be inserted with no space. The column member insertion hole 132 and the rib insertion hole 133 are provided to communicate with each other between the surface 1311 and the surface 1312. Furthermore, a height of the body part 131 of the third member 13 is shaped to be lower than a height of the second member 12 in the axial direction.

A diameter of the third member 13 is smaller than a diameter of the first member 11. However, the diameter is not limited to this, or it goes without saying that the diameters of the two members may be the same and the diameter of the first member 11 may be smaller than the diameter of the third member 13.

Furthermore, the first member 11 and the third member 13 have circular shapes in plan view. However, the shapes are not limited to this and may be any shape such as a polygonal shape (for example, square shape, regular hexagonal shape, regular octagonal shape, or the like), a rounded polygonal shape, an oval shape such as an elliptical shape or an oval shape, or the like. That is, it is sufficient that the base part 111 of the first member 11 have a flat plate shape and the third member 13 have a flat board shape as a whole.

Moreover, the shapes of the first member 11 and the third member 13 in plan view may be different from each other. For example, a combination of a rounded square first member 11 and a circular third member 13 or the like is possible.

The second member 12 and the third member 13 include the same metal material, and the first member 11 includes the metal material different from these. However, the first member 11 and the third member 13 may include the same metal material, and the second member 12 may include a metal material different from these, the first member 11 and the second member 12 may include the same metal material, and the third member 13 may include a metal material different from these, or all of the first member 11, the second member 12, and the third member 13 may include different metal materials.

Furthermore, as the metal materials, copper and aluminum are used. However, any combination of metal materials other than this may be used, and an alloy, not a single metal may be used.

### [Assembling]

FIG. 2 is a view illustrating assembling to assemble the first member 11, the second member 12, and the third member 13.

First, the annular rib 112 of the first member 11 is fitted into the rib insertion hole 133 of the third member 13. Next, the second member 12 is inserted into the column member insertion hole 132 of the third member 13, and is inserted into the annular rib 112 of the first member 11 as it is. When the first member 11, the second member 12, and the third member 13 are assembled, the second member 12 protrudes from the first surface 1311 of the third member 13. (refer to FIG. 1 at (a)) Note that, the order may be an order in which the second member 12 is inserted into the annular rib 112 of the first member 11, and then, the rib insertion hole 133 and the column member insertion hole 132 of the third member 13 are fitted to the second member 12 and the annular rib 112 of the first member 11.

### [Compressing and Joining]

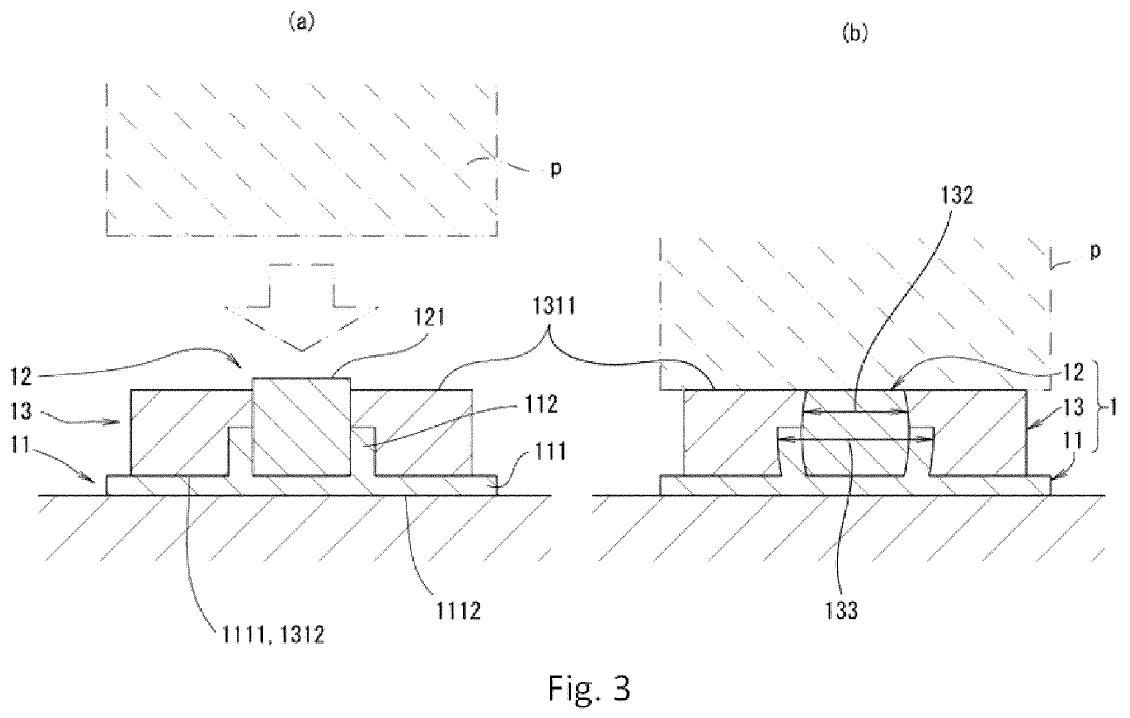

FIG. 3 is a view illustrating compressing and joining to compress and join the first member 11, the second member 12, and the third member 13 that are assembled; and FIG. 3 at (a) illustrates a state before joining, and FIG. 3 at (b) illustrates a state after joining.

Joining is performed using a press machine, and a second surface 1112 of the disk shaped base part 111 of the first member 11 and a surface 121 of the second member 12 protruding from the first surface 1311 of the third member 13 are pinched and compressed with the press machine.

With the compression, the second member 12 is crushed, and a side cross section (cross section including central axis of the second member 12 that is column member) is deformed into a barrel shape of which a central part in the axial direction is expanded. Then, when the second member 12 is expanded to the barrel shape, the second member 12 strongly presses the annular rib 112 of the first member 11 therearound and the column member insertion hole 132 and the rib insertion hole 133 of the third member 13 in an outer circumference direction.

Finally, at a time when a pressing part p of the press machine that compresses the second member 12 has contact with the first surface 1311 of the third member 13 (a time when a part of the second member 12 protruding from the first surface 1311 of the third member 13 is flush with the first surface 1311 of the third member 13), compressing is ended.

As a result of this compression, the annular rib 112 of the first member 11, the column member insertion hole 132, and the rib insertion hole 133 of the third member 13 are deformed to expand toward an outer circumference, in accordance with an outer shape of the second member 12 deformed into the barrel shape.

Then, since the respective members including the first member 11, the second member 12, and the third member 13 strongly press against each other between the members so that all of the first member 11, the second member 12, and the third member 13 are deformed, at a boundary face where the first member 11, the second member 12, and the third member 13 abut, these three members are firmly joined.

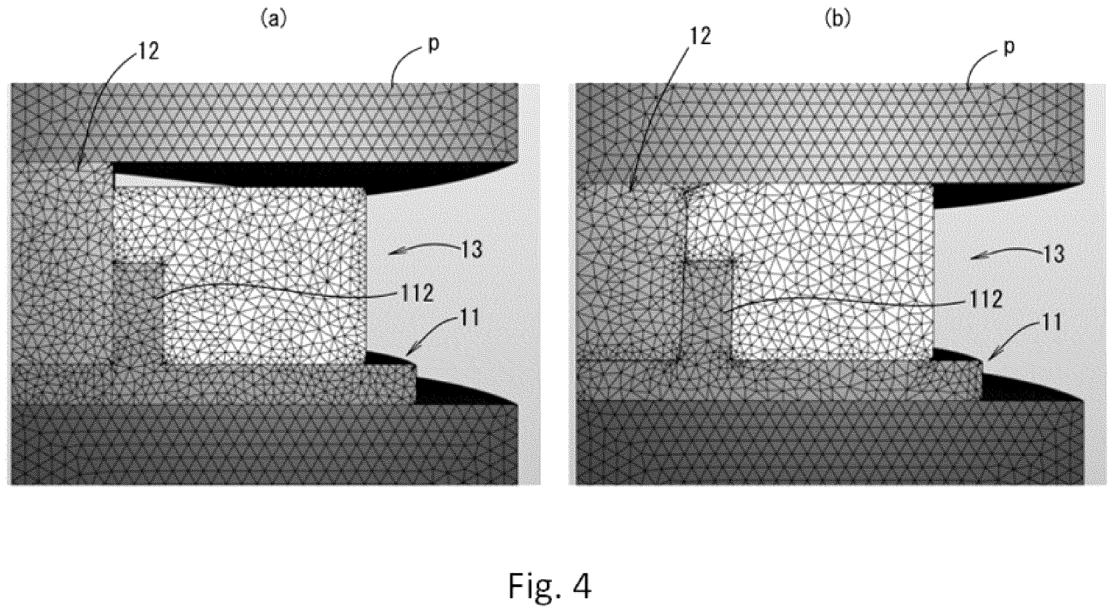

FIG. 4 is a view in which compressing and joining by the press machine is shaping-processed and simulated. As compared with FIG. 4 at (a) illustrating the state before joining, in FIG. 4 at (b) illustrating the state after joining, a state can be seen where the second member 12 is expanded in a barrel shape and the annular rib 112 of the first member 11 therearound and the rib insertion hole 133 of the third member 13 are also expanded to the outer circumference side.

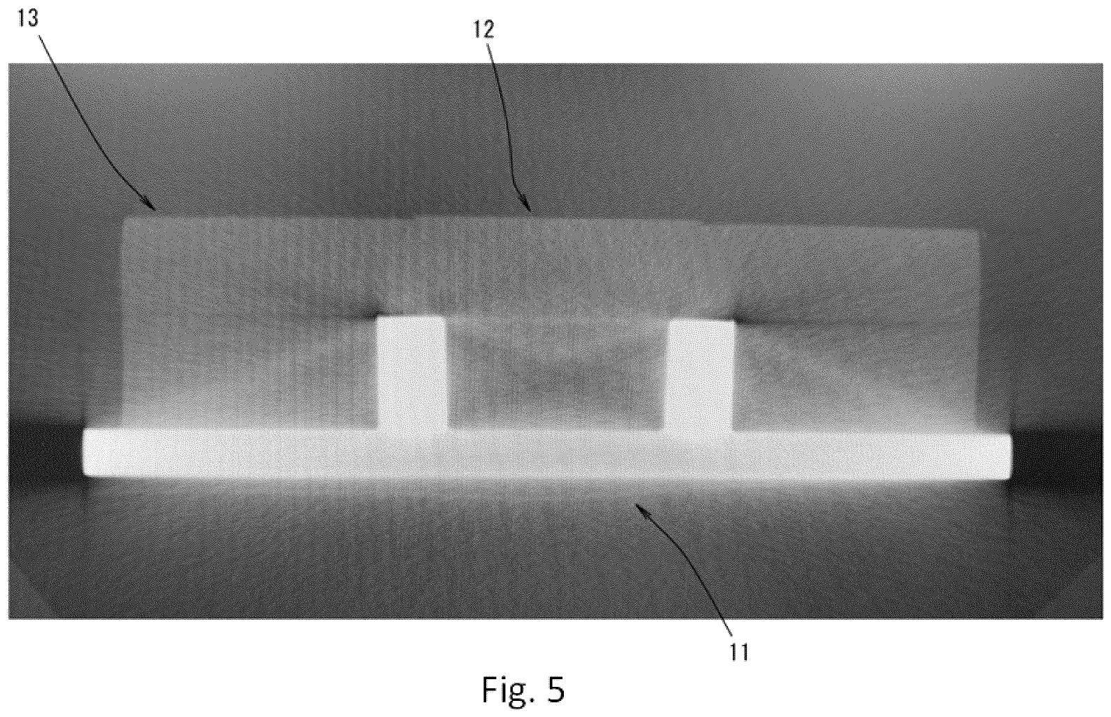

Furthermore, FIG. 5 is an X-ray CT image of the dissimilar metal joined body 1 after joining, and a state can be clearly seen where the first member 11, the second member 12, and the third member 13 are actually deformed to be expanded to the outer circumference side.

In this way, since the dissimilar metal joined body 1 can be joined in a step for only assembling each member and compressing with the press machine, high productivity can be realized.

### [Modification 1 of Embodiment 1]

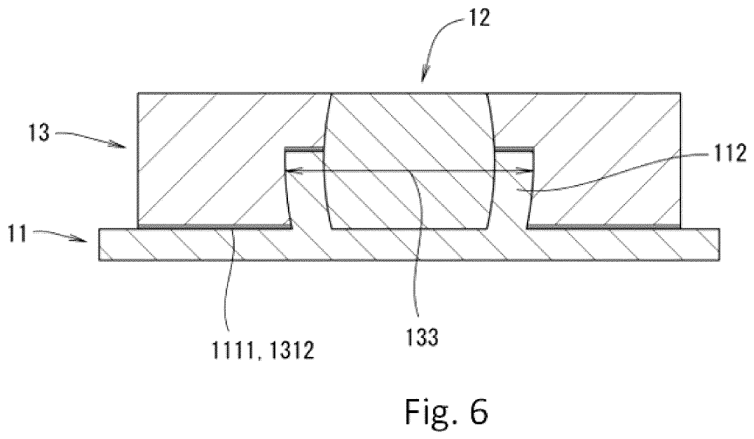

FIG. 6 illustrates a modification 1 of the Embodiment 1.

In the modification 1, ultrasonic joining is further added to the compressing and joining of the Embodiment 1, and joining strength is further enhanced.

In the dissimilar metal joined body 1 in which the first member 11, the second member 12, the third member 13 are expanded to the outer circumference side and compressed and joined, there is a case where joining of the boundary face intersecting with the central axis direction of the second member 12 that is the column member is not sufficient, as compared with joining of a boundary face intersecting with a radial direction.

Therefore, in order to increase the joining strength of the boundary face intersecting with the central axis direction, ultrasonic join is performed on the dissimilar metal joined body 1 compressed and joined with the press machine.

For example, ultrasonic join is performed on a boundary face between an outer part of the first surface 1111 of the base part 111 of the first member 11 than the annular rib 112 and the second surface 1312 of the third member 13 and a boundary face (thick line part in FIG. 6) between a top surface of the annular rib 112 of the first member 11 and a top surface of the rib insertion hole 133 of the third member 13, in the dissimilar metal joined body 1 obtained by the Embodiment 1.

That is, in the modification 1 of the Embodiment 1, ultrasonic joining is further added after compressing and joining.

In this way, by performing ultrasonic join on the boundary face intersecting with the central axis direction, the joining strength can be further enhanced.

Note that it goes without saying that ultrasonic join may be performed on a surface other than these boundary faces.

### [Modification 2 of Embodiment 1]

In the modification 1, ultrasonic join is performed on the dissimilar metal joined body 1 compressed and joined with the press machine. However, conversely, in a state where the first member 11, the second member 12, and the third member 13, before being compressed with the press machine, are assembled, ultrasonic join can be performed.

For example, the rib insertion hole 133 of the third member 13 is fitted into the annular rib 112 of the first member 11, and ultrasonic join is performed on an abutting part between an outer part of the first surface 1111 of the base part 111 of the first member 11 than the annular rib 112 and the second surface 1312 of the third member 13 and an abutting part between the top surface of the annular rib 112 of the first member 11 and the top surface of the rib insertion hole 133 of the third member 13 (thick line part in FIG. 6). Thereafter, the second member 12 is inserted into the column member insertion hole 132 of the third member 13 and the annular rib 112 of the first member 11.

Then, it is possible to obtain the dissimilar metal joined body 1, by compressing and joining an assembly of the first member 11 and the third member 13 on which ultrasonic joining has been performed, and the second member 12, with the press machine.

Note that, after the second member 12 is inserted into the annular rib 112 of the first member 11 and ultrasonic join is performed between the first member 11 and the second member 12, the column member insertion hole 132 and the rib insertion hole 133 of the third member 13 are fitted with the second member 12 and the annular rib 112 of the first member 11, and then, the dissimilar metal joined body 1 may be obtained by performing compressing and joining with the press machine.

That is, in the modification 2 of the Embodiment 1, ultrasonic joining is further added in the assembling.

Furthermore, the dissimilar metal joined body 1 may be obtained by performing compressing and joining with the press machine after ultrasonic join is performed between the first member 11 and the second member 12 and/or between the first member 11 and the third member 13 in a state where all the first member 11, the second member 12, and the third member 13 are assembled.

That is, in the modification 2 of the Embodiment 1, ultrasonic joining may be further added after assembling and before compressing and joining.

Note that it goes without saying that ultrasonic join may be performed on a surface other than these boundary faces.

### [Modification 3 of Embodiment 1]

In the modifications 1 and 2, ultrasonic join is used in combination with compression and joining with the press machine. However, friction join may be used in combination, instead of ultrasonic join.

Since it is not possible to perform friction join after compressing and joining with the press machine, friction join is performed before the compressing and joining with the press machine. For example, after the rib insertion hole 133 of the third member 13 is fitted with the annular rib 112 of the first member 11 and friction join is performed between the first member 11 and the third member 13, the second member 12 is inserted into the column member insertion hole 132 of the third member 13 and the annular rib 112 of the first member 11.

Thereafter, the dissimilar metal joined body 1 is obtained by compressing and joining an assembly of the first member 11, the third member 13, and the second member 12 on which friction join has been performed, with the press machine.

Note that, after the second member 12 is inserted into the annular rib 112 of the first member 11, friction join is performed between the first member 11 and the second member 12, and the column member insertion hole 132 and the rib insertion hole 133 of the third member 13 are fitted with the second member 12 and the annular rib 112 of the first member 11, compressing and joining may be performed with the press machine.

That is, in the modification 3 of the Embodiment 1, friction joining is further added in assembling.

Furthermore, the dissimilar metal joined body 1 may be obtained by performing compressing and joining with the press machine after friction join is performed between the first member 11 and the second member 12 and/or between the first member 11 and the third member 13 in a state where all the first member 11, the second member 12, and the third member 13 are assembled.

That is, in the modification 3 of the Embodiment 1, friction joining may be further added after assembling and before compressing and joining.

### Embodiment 2

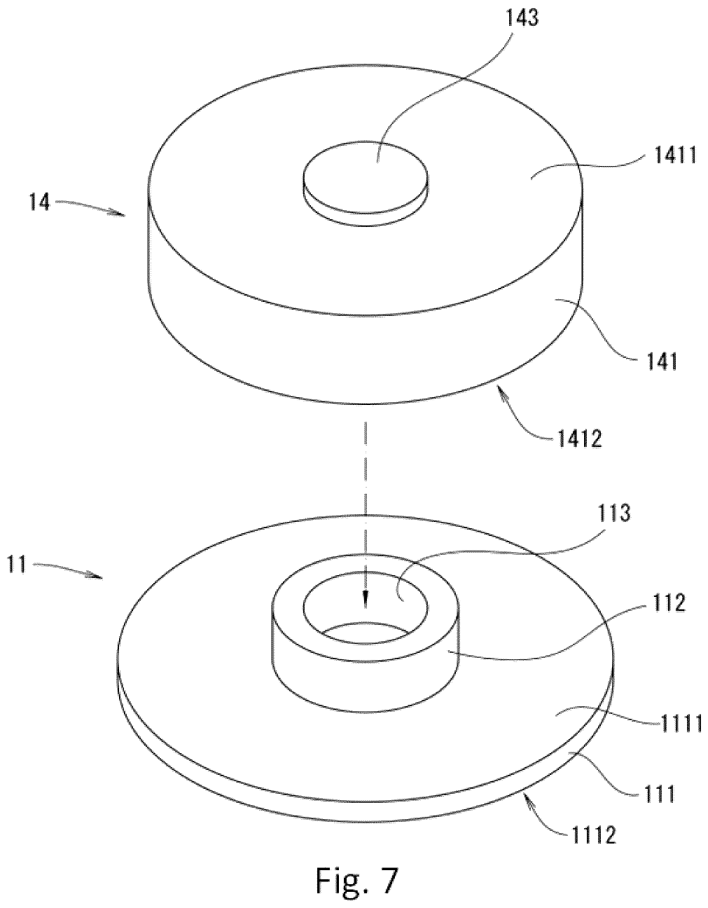

FIG. 7 is a view illustrating assembling for assembling a first member 11 and a fourth member 14 according to an Embodiment 2 of the present invention.

In the embodiment 1, the dissimilar metal joined body 1 is formed on the three metal members including the first member 11, the second member 12, and the third member 13. However, in the Embodiment 2, a dissimilar metal joined body 21 is formed of two metal members including the first member 11 and the fourth member 14. (it can be said that fourth member 14 is integration of second member 12 and third member 13)

Note that a perspective view of the dissimilar metal joined body 21 is similar to the perspective view of the dissimilar metal joined body 1 according to the Embodiment 1. Please refer to FIG. 1.

### [Configuration of Each Member]

The first member 11 is a member same as the first member 11 in the Embodiment 1, and is obtained by shaping copper, and includes a disk shaped base part 111 and an annular rib 112 that is provided to protrude at a central part on a first surface 1111 of the base part 111.

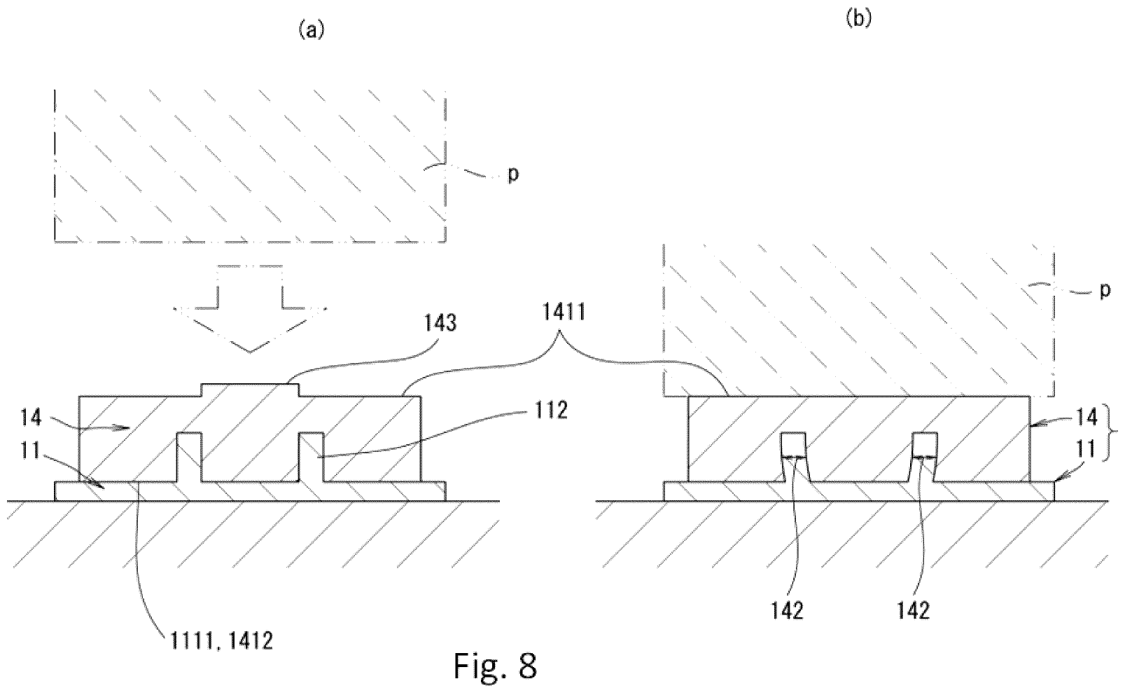

The fourth member 14 is a member obtained by shaping aluminum, and includes: a body part 141 that is formed in a disk-like shape as a whole, a protruding part 143 that is formed on a first surface 1411 of the body part 141 and protrudes from other area of the first surface 1411, and an annular groove part 142 (refer to FIG. 8) that is formed on a second surface 1412 of the body part 141 and into which the annular rib 112 of the first member 11 can be inserted with no space.

The protruding part 143 is provided in an area, of the first surface 1411 of the body part 141, that substantially faces an inner part of an inner circumference surface of the annular rib 112 of the first member when the first member 11 and the fourth member 14 are assembled.

A diameter of the fourth member 14 is smaller than a diameter of the first member 11. However, the diameter is not limited to this, and it goes without saying that the diameters of the two members may be the same or the diameter of the first member 11 may be smaller than the diameter of the fourth member 14.

Furthermore, the first member 11 and the fourth member 14 have circular shapes in plan view. However, the shapes are not limited to this and may be any shape such as a polygonal shape (for example, square shape, regular hexagonal shape, regular octagonal shape, or the like), an oval shape such as an elliptical shape or an oval shape, or the like.

Moreover, the shapes of the first member 11 and the fourth member 14 in plan view may be different from each other. For example, a combination of a square first member 11 and a circular fourth member 14 or the like is possible. That is, it is sufficient that the base part 111 of the first member 11 have a flat plate shape and the fourth member 14 have a flat board shape as a whole.

As metal materials, copper and aluminum are used. However, any combination of metal materials other than this may be used, and an alloy, not a single metal may be used.

### [Assembling]

The annular groove part 142 of the fourth member 14 is fitted with the annular rib 112 of the first member 11.

### [Compressing and Joining]

FIG. 8 is a view illustrating compressing and joining for compressing and joining the first member 11 and the fourth member 14 that are assembled; and FIG. 8 at (a) illustrates a state before joining, and FIG. 8 at (b) illustrates a state after joining.

Joining is performed using a press machine, and a second surface 1112 of the disk shaped base part 111 of the first member 11 and the protruding part 143 protruding from the first surface 1411 of the fourth member 14 are pinched and compressed with the press machine.

With the compression, the protruding part 143 of the fourth member 14 and a part below the protruding part 143 are crushed, and a part of the fourth member 14 enclosed in the annular rib 112 of the first member 11 is deformed into a barrel shape of which a central part of a side cross section (cross section including central axis of annular rib 112 of first member 11) in an axial direction is expanded. Then, when the part of the fourth member 14 enclosed in the annular rib 112 of the first member 11 is expanded to the barrel shape, the fourth member 14 strongly presses the annular rib 112 of the first member 11 therearound and the annular groove part 142 of the fourth member 14 in an outer circumference direction.

Finally, at a time when a pressing part p of the press machine that presses the fourth member 14 has contact with the first surface 1411 of the fourth member 14 (a time when a protruding part 143 of the fourth member 14 is flush with other area of the first surface 1411 of the fourth member 14), compressing is ended.

As a result of this compression, the annular rib 112 of the first member 11 and the annular groove part 142 of the fourth member 14 are deformed to expand to an outer circumference side, in accordance with an outer shape of the part of the fourth member 14, deformed in the barrel shape, enclosed in the annular rib 112 of the first member 11.

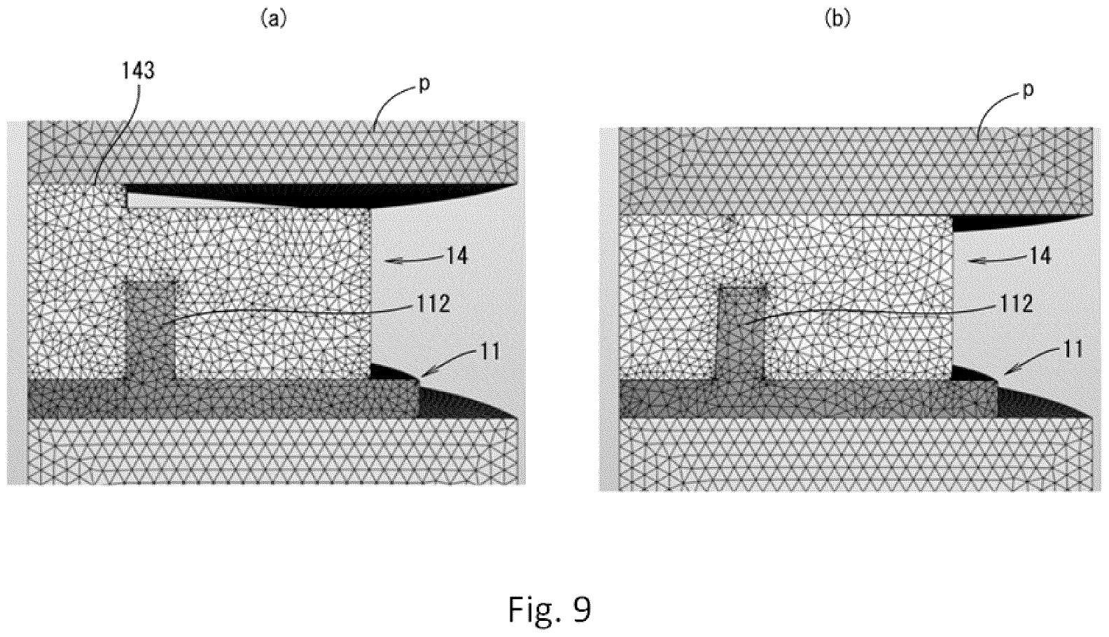

Then, since the first member 11 and the fourth member 14 are strongly pressed against each other so that the first member 11 and the fourth member 14 are deformed at a boundary face where the first member 11 and the fourth member 14 abut, these two members are firmly joined. FIG. 9 is a view in which compressing and joining by the press machine is shaping-processed and simulated. As compared with FIG. 9 at (a) illustrating the state before joining, in FIG. 9 at (b) illustrating the state after joining, a state can be seen where the part of the fourth member 14 enclosed in the annular rib 112 of the first member 11 is expanded to the barrel shape and the annular rib 112 of the first member 11 and the annular groove part 142 of the fourth member 14 therearound are expanded to the outer circumference side.

In this way, since the dissimilar metal joined body 21 can be joined in a step for only assembling each member and compressing with the press machine, high productivity can be realized. Furthermore, it can be said that the fourth member 14 in the Embodiment 2 is an integration of the second member 12 and the third member 13 in the Embodiment 1. In a case where the second member 12 and the third member 13 include the same material as in the Embodiment 1, the number of members is reduced by using the Embodiment 2, and productivity can be further improved.

### [Modification 4 of Embodiment 2]

In this modification 4, as in the modification 1 of the Embodiment 1, ultrasonic joining is further added to compressing and joining in the Embodiment 2, and a joining strength is further enhanced.

In the dissimilar metal joined body 21 in which the first member 11 and the fourth member 14 are expanded to the outer circumference side and joined, there is a case where joining of the boundary face intersecting with the central axis direction of the annular rib 112 of the first member 11 is not sufficient as compared with joining of the boundary face intersecting with the radial direction.

Therefore, in order to increase the joining strength of the boundary face intersecting with the central axis direction, ultrasonic join is performed on the dissimilar metal joined body 21 compressed and joined with the press machine.

For example, ultrasonic join is performed on: a boundary face between a part of the first surface 1111 of the base part 111 of the first member 11 outer than the annular rib 112 and a part of the second surface 1412 of the fourth member 14 outer than the annular groove part 142, and a boundary face between a top surface of the annular rib 112 of the first member 11 and the annular groove part 142 of the fourth member 14, in the dissimilar metal joined body 21 obtained by the Embodiment 2.

That is, in the modification 4 of the Embodiment 2, ultrasonic joining is further added after compressing and joining.

Note that it goes without saying that ultrasonic join may be performed on a surface other than these boundary faces.

### [Modification 5 of Embodiment 2]

In the modification 4, ultrasonic join is performed on the dissimilar metal joined body 21 compressed and joined with the press machine. However, conversely, in a state where the first member 11 and the fourth member 14, before being compressed with the press machine, are assembled, ultrasonic join can be performed.

For example, in a state where the first member 11 and the fourth member 14, before being compressed with the press machine, are assembled, ultrasonic join is performed on an abutting part between a part of the first surface 1111 of the base part 111 of the first member 11 outer than the annular rib 112 and a part of the second surface 1412 of the fourth member 14 outer than the annular groove part 142, and an abutting part between the top surface of the annular rib 112 of the first member 11 and the annular groove part 142 of the fourth member 14.

Then, the dissimilar metal joined body 21 is obtained by compressing and joining an assembly of the first member 11 and the fourth member 14, on which ultrasonic join has been performed, with the press machine.

That is, in the modification 5 of the Embodiment 2, ultrasonic joining is further added after assembling and before compressing and joining.

Note that it goes without saying that ultrasonic join may be performed on an abutting part other than these abutting parts.

### [Modification 6 of Embodiment 2]

In the modifications 4 and 5, ultrasonic join is used in combination with compressing and joining with the press machine. However, friction join may be used in combination, instead of ultrasonic join.

Since it is not possible to perform friction join after compressing and joining with the press machine, friction join is performed before the compressing and joining with the press machine. For example, the annular groove part 142 of the fourth member 14 is fitted with the annular rib 112 of the first member 11, and friction join is performed between the first member 11 and the fourth member 14.

Thereafter, the first member 11 and the fourth member 14, on which friction join has been performed, are compressed and joined with the press machine, so as to obtain the dissimilar metal joined body 21.

That is, in the modification 6 of the Embodiment 2, friction joining is further added after assembling and before compressing and joining.

### Embodiment 3

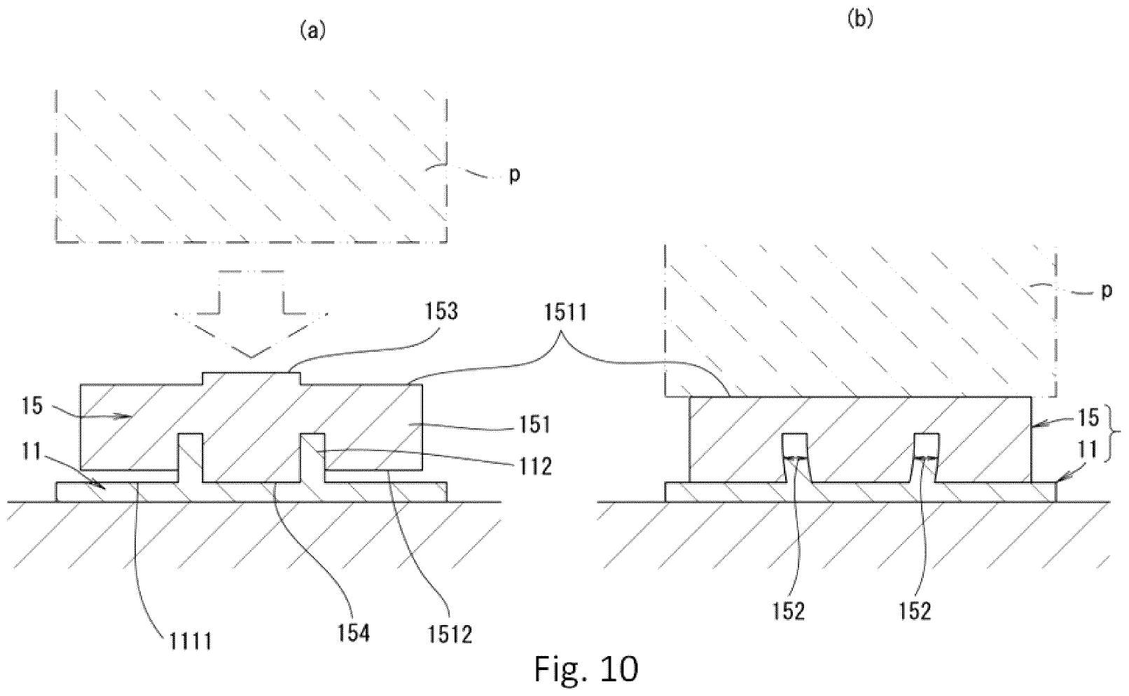

FIG. 10 is a view illustrating compressing and joining for compressing and joining a first member 11 and a fifth member 15 according to an Embodiment 3 of the present invention.

As in the Embodiment 2, a dissimilar metal joined body 31 is formed of two metal members including the first member 11 and the fifth member 15.

Note that a perspective view of the dissimilar metal joined body 31 is similar to the perspective view of the dissimilar metal joined body 1 according to the Embodiment 1. Please refer to FIG. 1.

### [Configuration of Each Member]

The first member 11 is a member same as the first member 11 in the Embodiment 1, and is obtained by shaping copper, and includes a disk shaped base part 111 and an annular rib 112 that is provided to protrude at a central part on a first surface 1111 of the base part 111.

The fifth member 15 is a member obtained by shaping aluminum, and includes: a body part 151 formed in a disk-like shape as a whole, a first protruding part 153 that is formed on a first surface 1511 of the body part 151 and protrudes from other area of the first surface 1511, an annular groove part 152 (refer to FIG. 10) that is formed on a second surface 1512 of the body part 151 and into which the annular rib 112 of the first member 11 can be inserted with no space, and a second protruding part 154 that is formed on the second surface 1512 of the body part 151 and protrudes from other area of the second surface 1512.

The first protruding part 153 is provided in an area, of the first surface 1511 of the body part 151, that substantially faces an inner part of an inner circumference surface of the annular rib 112 of the first member when the first member 11 and the fifth member 15 are assembled. Furthermore, the second protruding part 154 is provided in an area, of the second surface 1512 of the body part 151, to be inserted into the inner part of the inner circumference surface of the annular rib 112 of the first member when the first member 11 and the fifth member 15 are assembled.

A diameter of the fifth member 15 is smaller than a diameter of the first member 11. However, the diameter is not limited to this, and it goes without saying that the diameters of the two members may be the same or the diameter of the first member 11 may be smaller than the diameter of the fifth member 15.

Furthermore, the first member 11 and the fifth member 15 have circular shapes in plan view. However, the shapes are not limited to this and may be any shape such as a polygonal shape (for example, square shape, regular hexagonal shape, regular octagonal shape, or the like), an oval shape such as an elliptical shape or an oval shape, or the like.

Moreover, the shapes of the first member 11 and the fifth member 15 in plan view may be different from each other. For example, a combination of a square first member 11 and a circular fifth member 15 or the like is possible. That is, it is sufficient that the base part 111 of the first member 11 have a flat plate shape and the fifth member 15 have a flat board shape as a whole.

As metal materials, copper and aluminum are used. However, any combination of metal materials other than this may be used, and an alloy, not a single metal may be used.

### [Assembling]

The annular groove part 152 of the fifth member 15 is fitted with the annular rib 112 of the first member 11.

In a state where the fifth member 15 is assembled to the first member 11, there is a space of an amount same as an amount by which the second protruding part 154 of the fifth member 15 protrudes, between the part of the first surface 1111 of the first member 11 outer than the annular rib 112 and the part of the second surface 1512 of the fifth member 15 outer than the annular groove part 152. (refer to FIG. 10 at (a))

### [Compressing and Joining]

FIG. 10 is a view illustrating compressing and joining for compressing and joining the first member 11 and the fifth member 15 that are assembled; and FIG. 10 at (a) illustrates a state before joining, and FIG. 10 at (b) illustrates a state after joining.

Joining is performed using a press machine, and the second surface 1112 of the disk shaped base part 111 of the first member 11 and the first protruding part 153 protruding from the first surface 1511 of the fifth member 15 are pinched and compressed with the press machine.

With the compression, the first protruding part 153 and the second protruding part 154 of the fifth member 15, and a part between the first protruding part 153 and the second protruding part 154 are crushed; and a part of the fifth member 15 enclosed in the annular rib 112 of the first member 11 is deformed into a barrel shape of which a central part of a side cross section (cross section including central axis of annular rib 112 of first member 11) in an axial direction is expanded. Then, when the part of the fifth member 15 enclosed in the annular rib 112 of the first member 11 is expanded to the barrel shape, the fifth member 15 strongly presses the annular rib 112 of the first member 11 therearound and the annular groove part 152 of the fifth member 15 in an outer circumference direction.

Then, the first protruding part 153 of the fifth member 15 is crushed, and the pressing part p of the press machine for compressing the fifth member 15 has contact with the first surface 1511 of the fifth member 15. (The first protruding part 153 of the fifth member 15 becomes flush with the other area of the first surface 1511 of the fifth member 15.)

Moreover, when the compression is continued with the press machine, the annular rib 112 of the first member 11 is crushed and deformed, and the space between the part of the first surface 1111 of the first member 11 outer than the annular rib 112 and the part of the second surface 1512 of the fifth member 15 outer than the annular groove part 152 decreases.

Finally, at a time when the part of the second surface 1512 of the fifth member 15 outer than the annular groove part 152 abuts the part of the first surface 1111 of the first member 11 outer than the annular rib 112 (a time when a second protruding part 154 of the fifth member becomes substantially flush with other area of the second surface 1512 of the fifth member), compressing is ended. At this time, the space between the part of the first surface 1111 of the first member 11 outer than the annular rib 112 and the part of the second surface 1512 of the fifth member 15 outer than the annular groove part 152 is almost eliminated, and the part of the first surface 1111 of the first member 11 outer than the annular rib 112 and the part of the second surface 1512 of the fifth member outer than the annular groove part 152 are strongly joined.

As a result of this compression, the annular rib 112 of the first member 11 and the annular groove part 152 of the fifth member 15 are deformed to expand to the outer circumference side, in accordance with an outer shape of the part of the fifth member 15, deformed in the barrel shape, enclosed in the annular rib 112 of the first member 11.

Then, since the first member 11 and the fifth member 15 are strongly pressed against each other so that the first member 11 and the fifth member 15 are deformed at a boundary face where the first member 11 and the fifth member 15 abut, these two members are firmly joined.

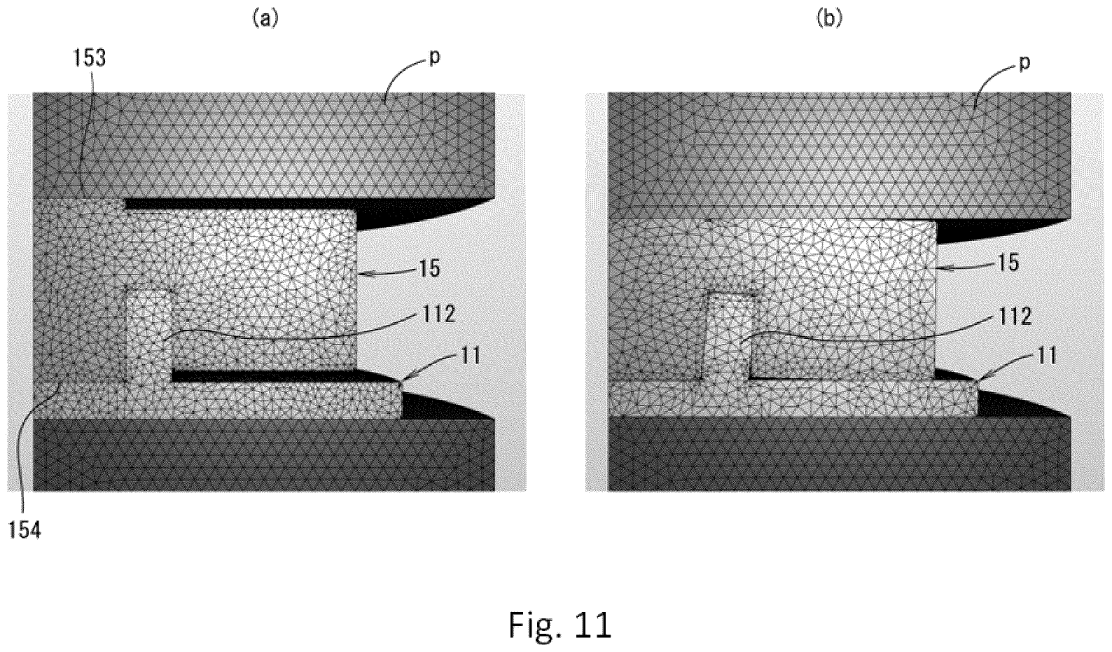

FIG. 11 is a view in which compressing and joining by the press machine is shaping-processed and simulated. As compared with FIG. 11 at (a) illustrating the state before joining, in FIG. 11 at (b) illustrating the state after joining, a state can be seen where the space between the part of the first surface 1111 of the first member 11 outer than the annular rib 112 and the part of the second surface 1512 of the fifth member 15 outer than the annular groove part 152 is substantially eliminated, the part of the fifth member 15 enclosed in the annular rib 112 of the first member 11 is expanded in the barrel shape, and the annular rib 112 of the first member 11 therearound and the annular groove part 152 of the fifth member 15 are expanded to the outer circumference side.

In this way, since the dissimilar metal joined body 31 can be joined in a step for only assembling each member and performing compressing with the press machine, high productivity can be realized.

Furthermore, it can be said that the fifth member 15 in the Embodiment 3 is an integration of the second member 12 and the third member 13 in the Embodiment 1, similarly to the fourth member 14 in the Embodiment 2. In a case where the second member 12 and the third member 13 include the same material as in the Embodiment 1, the number of members is reduced by using the Embodiment 3, and the productivity can be further improved.

Furthermore, as compared with the Embodiments 1 and 2, the part of the fifth member 15 enclosed in the annular rib 112 of the first member 11 and the annular rib 112 of the first member 11 are more greatly deformed. Therefore, the joining strength can be further enhanced.

### [Modification 7 of Embodiment 3]

In this modification 7, as in the modification 4 of the Embodiment 2, ultrasonic joining is further added to compressing and joining in the Embodiment 3, and a joining strength is further enhanced.

In the dissimilar metal joined body 31 in which the first member 11 and the fifth member 15 are expanded to the outer circumference side and joined, there is a case where joining of the boundary face intersecting with the central axis direction of the annular rib 112 of the first member 11 is not sufficient as compared with joining of a boundary face intersecting with a radial direction.

Therefore, in order to increase the joining strength of the boundary face intersecting with the central axis direction, ultrasonic join is performed on the dissimilar metal joined body 31 compressed and joined with the press machine.

For example, ultrasonic join is performed on a boundary face between the part of the first surface 1111 of the base part 111 of the first member 11 outer than the annular rib 112 and the part of the second surface 1512 of the fifth member 15 outer than the annular groove part 152 and a boundary face between the top surface of the annular rib 112 of the first member 11 and the annular groove part 152 of the fifth member 15, in the dissimilar metal joined body 31 obtained by the Embodiment 3.

That is, in the modification 7 of the Embodiment 3, ultrasonic joining is further added after compressing and joining.

Note that it goes without saying that ultrasonic join may be performed on a surface other than these boundary faces.

### [Modification 8 of Embodiment 2]

In the modification 7, ultrasonic join is performed on the dissimilar metal joined body 31 compressed and joined with the press machine. However, conversely, in a state where the first member 11 and the fifth member 15, before being compressed with the press machine, are assembled, ultrasonic join can be performed.

For example, in a state where the first member 11 and the fifth member 15, before being compressed with the press machine, are assembled, ultrasonic join is performed on an abutting part between the part of the first surface 1111 of the base part 111 of the first member 11 inner than the annular rib 112 and the second protruding part 154 of the fifth member 15 and an abutting part between the top surface of the annular rib 112 of the first member 11 and the annular groove part 152 of the fifth member 15.

Then, the dissimilar metal joined body 31 is obtained by compressing and joining an assembly of the first member 11 and the fifth member 15, on which ultrasonic join has been performed, with the press machine.

That is, in the modification 8 of the Embodiment 3, ultrasonic joining is further added after assembling and before compressing and joining.

Note that it goes without saying that ultrasonic join may be performed on an abutting part other than these abutting parts.

### [Modification 9 of Embodiment 3]

In the modifications 7 and 8, ultrasonic join is used in combination with compressing and joining with the press machine. However, friction join may be used in combination, instead of ultrasonic join.

Since it is not possible to perform friction join after compressing and joining with the press machine, friction join is performed before the compressing and joining with the press machine. For example, the annular groove part 152 of the fifth member 15 is fitted with the annular rib 112 of the first member 11, and friction join is performed between the first member 11 and the fifth member 15.

Thereafter, the first member 11 and the fifth member 15, on which friction join has been performed, are compressed and joined with the press machine, so as to obtain the dissimilar metal joined body 31.

That is, in the modification 9 of the Embodiment 3, friction joining is further added after assembling and before compressing and joining.

### Embodiment 4

In the Embodiment 3, the fifth member 15, in which the first protruding part 153 is formed on the first surface 1511 of the body part 151 and the second protruding part 154 is formed on the second surface 1512, has been used. However, the fifth member 15 may be used, in which the first protruding part 153 formed on the first surface 1511 on the opposite side to the first member 11, of these two parts including the first protruding part 153 and the second protruding part 154, is omitted.

That is, as a sixth member, a member in which a surface of the body part on the opposite side to the first member 11 is a flat surface and a protruding part is formed on a surface on the side of the first member 11 may be used.

### [Applications of Dissimilar Metal Joined Body]

For example, the dissimilar metal joined body 1 can be used as a heat sink that dissipates heat of an electronic component or the like.

In such a case, it is sufficient that the first member 11 and the third member 13 be formed of copper, the second member 12 be formed of aluminum, and the side of the first member 11 be used as abutting on the electronic component or the like. The first member 11 and the third member 13 can more efficiently dissipate heat because copper has a higher thermal conductivity than aluminum, and a weight and cost can be reduced by forming the second member that is a part of the center of the dissimilar metal joined body 1 using aluminum because aluminum is lighter and less expensive than copper. Moreover, resources can be saved by replacing a material, such as copper, for which depletion of resources is concerned, with a different material.

Furthermore, in the dissimilar metal joined body 1, the first member, the second member, and the third member are firmly joined. Therefore, the dissimilar metal joined body 1 has a high thermal conductivity between the members and can efficiently dissipate heat from the electronic component or the like.

As a heat sink, by forming the first member 11 of aluminum and forming the second member 12 and the third member 13 of copper, it can be used as abutting on the electronic component or the like. In this case, since the base part 111 of the first member 11 is relatively thin, the heat dissipation from the electronic component or the like is not greatly hindered, and the weight and the cost can be reduced as described above.

In addition, it can be used as an electrode 4 of a relatively large lithium ion battery.

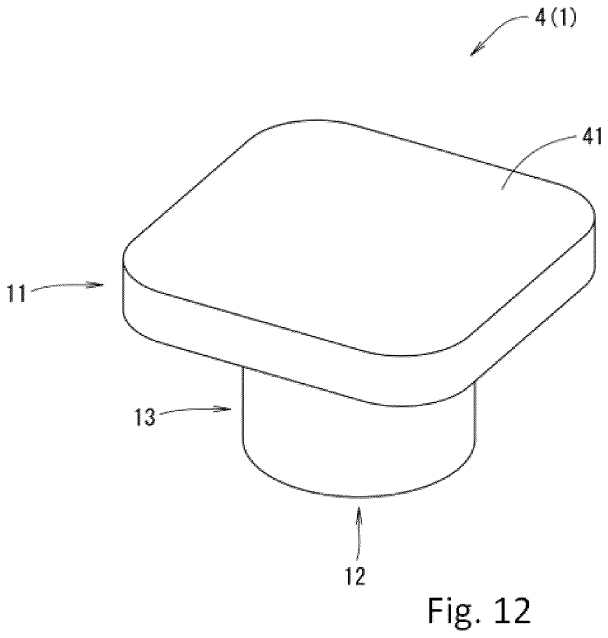

In such a case, by forming the first member 11 of aluminum and forming the second member 12 and the third member 13 of copper (refer to FIG. 12), or conversely, forming the first member 11 of copper and forming the second member 12 and the third member 13 of aluminum, it is sufficient to use an aluminum side as a terminal surface 41 of an electrode for connecting conductive wire.

Since copper has a higher conductivity than aluminum, it is preferable to form the electrode with copper. However, there is a case where the conductive wire is connected to the electrode of the relatively large lithium ion battery by welding, aluminum has higher compatibility with welding than copper, as the terminal surface of the electrode. Therefore, it is sufficient to form the first surface of the dissimilar metal joined body only with aluminum. Considering that the related art in which different metal materials are exposed in the same plane is not suitable for such a use method, this is a great advantage of the dissimilar metal joined body 1 of this case.

Furthermore, since the first member, the second member, and the third member are firmly joined in the dissimilar metal joined body 1, the dissimilar metal joined body 1 has a small electric resistance between the members and can efficiently extract a current from a battery.

Furthermore, in a case where the first surface of the dissimilar metal joined body is formed of only one type of metal in this way, the dissimilar metal joined bodies 21 and 31 can also be used.

In such a case, it is sufficient that one of the first member 11 or the fourth member 14 and the first member 11 or the fifth member 15 be formed of copper and the other be formed of aluminum.

In the above, the heat sink and the electrode have been exemplified as examples of the applications of the dissimilar metal joined bodies 1, 21, and 31. However, the dissimilar metal joined bodies 1, 21, and 31 can be optimized and used in accordance with other various applications, due to characteristics of the dissimilar metal joined bodies 1, 21, and 31 in which only one type of metal is exposed on each of both surfaces and both surfaces can be formed of different metals and the dissimilar metal joined body 1 in which two different types of metal are exposed on the first surface and only one type of metal is exposed on the second surface.

Furthermore, applications of the dissimilar metal joined body 1 are further widened by setting the different metals as the three members.

As described above, the dissimilar metal joined bodies 1, 21, and 31 according to the Embodiments of the present invention have been described in detail with reference to the drawings. However, a specific configuration is not limited to these Embodiments, and design changes or the like without departing from the gist of the present invention is included in the present invention.

Furthermore, the Embodiments described above can be combined by diverting their techniques as long as there is no particular contradiction or problems in the purpose, the configuration, or the like.

### REFERENCE SIGNS LIST

1, 21, 31: Dissimilar metal joined body
11: First member
111: Base part
1111: First surface
1112: Second surface
112: Rib
113: Inner circumference part
12: Second member
121: Surface
13: Third member
131: Body part
1311: First surface
1312: Second surface
132: Column member insertion hole
133: Rib insertion hole
14: Fourth member
141: Body part
1411: First surface
1412: Second surface
142: Annular groove part
143: Protruding part
15: Fifth member
151: Body part
1511: First surface
1512: Second surface
152: Annular groove part
153: First protruding part
154: Second protruding part
4: Electrode
41: Terminal surface
P: Pressing part of press machine

1. A dissimilar metal joined body in which three or more members including at least a first member, a second member, and a third member are joined, wherein
at least the first member and the second member are metal members each including one type of metal, different for each of the first member and the second member and selected from among two or more types of metals,
the first member has a flat plate shaped base part and an annular rib on a first surface of the flat plate shaped base part,
the second member is a column member and is provided in an inner circumference surface of the annular rib of the first member,
the third member has a substantially flat board shape, in which the second member is in a column member insertion hole formed on a first surface of the third member, and the annular rib of the first member is in a rib insertion hole formed on a second surface of the third member, and
on a cross section including a central axis of the annular rib, the second member is shaped in a barrel shape, the annular rib is shaped in a shape expanded to an outer circumference side along an outer shape of the barrel shape of the second member, and the rib insertion hole of the third member is shaped in a shape expanded to the outer circumference side along the expanded shape of the annular rib.

2. A method for joining a dissimilar metal joined body in which three or more members including at least a first member, a second member, and a third member are joined,
at least the first member and the second member being metal members each including one type of metal, different for each of the first member and the second member and selected from among two or more types of metals,
the first member having a flat plate shaped base part and an annular rib on a first surface of the flat plate shaped base part,
the second member being a column member that is inserted into an inner circumference surface of the annular rib of the first member and is higher than a height of the annular rib,
the third member having a substantially flat board shape lower than a height of the second member and having a column member insertion hole on a first surface in which the second member can be inserted, and having an annular rib insertion hole, on a second surface, which communicates with the column member insertion hole and into which the annular rib of the first member and an inner circumference part of the annular rib can be inserted,
the method comprising:
assembling through inserting the annular rib of the first member into the rib insertion hole of the third member and through inserting the second member into the column member insertion hole of the third member and the annular rib of the first member; and
compressing and joining through compressing the first member, the second member, and the third member assembled by the assembling by pinching the second member protruding from the second surface of the third member and a surface of the first member where the annular rib is not formed and ending the compression at a time when a protruding part of the second member is flush with the second surface of the third member, so as to join the three or more members.

3. The method for joining the dissimilar metal joined body according to claim 2, further comprising:
ultrasonic joining or friction joining through abutting at least the first member and the third member in the assembling and performing ultrasonic join or friction join on a part where at least the first surface of the flat plate shaped base part of the first member and/or a top surface of the annular rib and the third member abut, during the assembling, or after the assembling and before the compressing and joining.

4. The method for joining the dissimilar metal joined body according to claim 2, further comprising:
ultrasonic joining through performing ultrasonic join on a part where at least the first surface of the flat plate shaped base part of the first member and/or a top surface of the annular rib and the third member abut, after the compressing and joining.

5. A dissimilar metal joined body in which two or more members including at least a first member and a second member are joined, wherein
at least the first member and the second member are metal members each including one type of metal, different for each of the first member and the second member and selected from among two or more types of metals,
the first member has a flat plate shaped base part and an annular rib on a first surface of the flat plate shaped base part,
the second member has a substantially flat board shape in which the annular rib of the first member is provided in an annular groove part formed in a first surface of the second member, and
on a cross section including a central axis of the annular rib, a part of the second member in the annular rib of the first member is shaped in a barrel shape, the annular rib is shaped in a shape expanded to an outer circumference side along an outer shape of the barrel shape of the part of the second member in the annular rib of the first member, and the annular groove part of the second member is shaped in a shape expanded to the outer circumference side along the expanded shape of the annular rib.

6. A method for joining a dissimilar metal joined body in which two or more members including at least a first member and a second member are joined,
at least the first member and the second member being metal members each including one type of metal, different for each of the first member and the second member and selected from among two or more types of metals,
the first member having a flat plate shaped base part and an annular rib on a first surface of the flat plate shaped base part,
the second member having a substantially flat board shape, having a first protruding part for protruding an area, which substantially faces an inner part of an inner circumference surface of the annular rib when the first member and the second member are assembled, from other area, on a first surface, and having an annular groove part into which the annular rib can be inserted, on a second surface,
the method comprising:
assembling through inserting the annular rib of the first member into the annular groove part of the second member; and
compressing and joining through compressing the first member and the second member assembled by the assembling by pinching the first protruding part of the second member and a surface of the first member where the annular rib is not formed and ending the compression at a time when the first protruding part of the second member is flush with the other area of the first surface of the second member, so as to join the two or more members.

7. A method for joining a dissimilar metal joined body according to claim 6, wherein
the second member has a second protruding part for protruding an area, which is inserted into the inner part of the inner circumference surface of the annular rib when the first member and the second member are assembled, from other area, on the second surface,
the method comprising:
compressing and joining through ending the compression at a time when the first protruding part of the second member is flush with the other area of the first surface of the second member and the second protruding part of the second member is flush with the other area of the second surface of the second member, so as to join the two or more members.

8. A method for joining a dissimilar metal joined body according to claim 7, wherein
a first surface of the second member is a flat surface without the first protruding part,
the method comprising:
compressing and joining for compressing the first member and the second member assembled by the assembling by pinching the first surface of the second member and a surface of the first member where the annular rib is not formed and ending the compression at a time when the second protruding part of the second member is flush with the other area of the second surface of the second member, so as to join the two or more members.

9. The method for joining the dissimilar metal joined body according to claim 6, further comprising:
ultrasonic joining or friction joining through abutting at least the first member and the second member in the assembling and performing ultrasonic join or friction join on a part where at least the first surface of the flat plate shaped base part of the first member and/or a top surface of the annular rib and the second member abut, during the assembling or after the assembling and before the compressing and joining.

10. The method for joining the dissimilar metal joined body according to claim 6, further comprising:
ultrasonic joining through performing ultrasonic join on a part where at least the first surface of the flat plate shaped base part of the first member and/or a top surface of the annular rib and the second member abut, after the compressing and joining.

11. The method for joining the dissimilar metal joined body according to claim 7, further comprising:
ultrasonic joining or friction joining through abutting at least the first member and the second member in the assembling and performing ultrasonic join or friction join on a part where at least the first surface of the flat plate shaped base part of the first member and/or a top surface of the annular rib and the second member abut, during the assembling or after the assembling and before the compressing and joining.

12. The method for joining the dissimilar metal joined body according to claim 8, further comprising:
ultrasonic joining or friction joining through abutting at least the first member and the second member in the assembling and performing ultrasonic join or friction join on a part where at least the first surface of the flat plate shaped base part of the first member and/or a top surface of the annular rib and the second member abut, during the assembling or after the assembling and before the compressing and joining.

13. The method for joining the dissimilar metal joined body according to claim 7, further comprising:
ultrasonic joining through performing ultrasonic join on a part where at least the first surface of the flat plate shaped base part of the first member and/or a top surface of the annular rib and the second member abut, after the compressing and joining.

14. The method for joining the dissimilar metal joined body according to claim 8, further comprising:
ultrasonic joining through performing ultrasonic join on a part where at least the first surface of the flat plate shaped base part of the first member and/or a top surface of the annular rib and the second member abut, after the compressing and joining.
